(19) United States
(12) Patent Application Publication
(10) Pub. No.: US 2025/0096049 A1
(43) Pub. Date: Mar. 20, 2025

(54) SEMICONDUCTOR DEVICE

(71) Applicant: Mitsubishi Electric Corporation, Tokyo (JP)

(72) Inventors: Tatsuya UDA, Fukuoka (JP); Taketo NISHIYAMA, Tokyo (JP)

(73) Assignee: Mitsubishi Electric Corporation, Tokyo (JP)

(21) Appl. No.: 18/764,060

(22) Filed: Jul. 3, 2024

(30) Foreign Application Priority Data
Sep. 20, 2023 (JP) 2023-151829

(51) Int. Cl. H01L 23/04; H01L 23/00; H01L 23/10

(52) U.S. Cl. CPC H01L 23/04; H01L 23/10; H01L 24/32; H01L 24/48; H01L 24/73; H01L 2224/32225; H01L 2224/48155; H01L 2224/73265; H01L 2924/1815

(57) ABSTRACT

A semiconductor device includes a case that accommodates a semiconductor chip therein, a sealing material injected into the case, and a lid fitted into an opening of the case. The lid includes a first lid member and a second lid member that partially overlap each other. The first lid member has a first notch portion and a first convex portion in a portion overlapping with the second lid member. The second lid member has a second notch portion and a second convex portion in a portion overlapping with the first lid member. The first lid member and the second lid member are combined each other with the second convex portion being inserted into the first notch portion and the first convex portion being inserted into the second notch portion.

### BACKGROUND OF THE INVENTION

### Field of the Invention

The present disclosure relates to a technique for sealing a semiconductor device.

### Description of the Background Art

For example, as a sealing structure for a semiconductor device for power control, a structure is known in which a sealing material is injected into a case in which a semiconductor chip, a wire, and the like, are accommodated, and a lid is further fitted into the opening of the case (For example, Japanese Patent Application Laid-Open No. 5-175351).

In the semiconductor device having such an above structure, the lid expands due to heat generated during operation, applying pressure to the lid from the inner wall of the case, causing warping of the lid, and in some cases, leading to damage to the lid.

### SUMMARY

An object of the present disclosure is to suppress warping of a lid due to heat generation of a semiconductor device.

According to the present disclosure, a semiconductor device includes a case that accommodates a semiconductor chip therein, a sealing material injected into the case, and a lid fitted into an opening of the case. The lid includes a first lid member and a second lid member that partially overlap each other. The first lid member has a first notch portion and a first convex portion in a portion overlapping with the second lid member. The second lid member has a second notch portion and a second convex portion in a portion overlapping with the first lid member. The first lid member and the second lid member are combined each other with the second convex portion being inserted into the first notch portion and the first convex portion being inserted into the second notch portion.

According to the semiconductor device of the present disclosure, warping of the lid due to heat generation of the semiconductor device is suppressed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a configuration of a semiconductor device according to Embodiment 1;

FIG. 2 is a top view of a lid of the semiconductor device according to Embodiment;

FIG. 3 is a side view of a first lid member of the lid of the semiconductor device according to Embodiment 1;

FIG. 4 is a side view of a second lid member of the lid of the semiconductor device according to Embodiment 1;

FIG. 5 is a cross-sectional view illustrating a configuration of a semiconductor device according to Embodiment 2;

FIG. 6 is a side view of a lid of a semiconductor device according to Embodiment 3;

FIG. 7 is a side view of a lid of a semiconductor device according to Embodiment 4; and

FIG. 8 is a side view of a lid of a semiconductor device according to Embodiment 5.

### DESCRIPTION OF THE PREFERRED EMBODIMENTS

### Embodiment 1

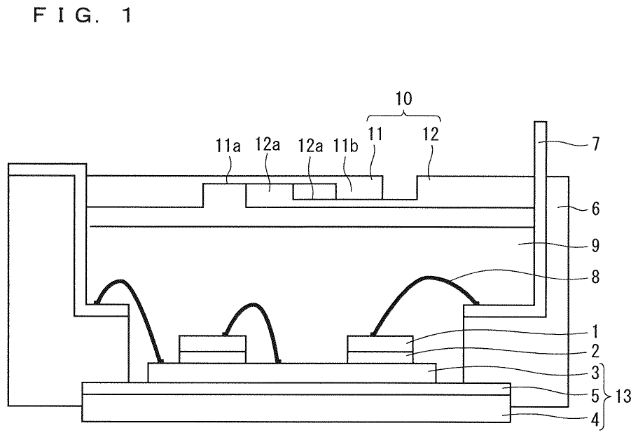

FIG. 1 is cross-sectional view illustrating a configuration of a semiconductor device according to Embodiment 1. As illustrated in FIG. 1, the semiconductor device according to Embodiment 1 includes an insulating substrate 13 including an insulating layer 5 provided on a metal plate 4 and a circuit pattern 3 provided on the insulating layer 5. Also, a semiconductor chip 1 is mounted on the insulating substrate 13 via a bonding member 2 such as solder. Note that the metal plate 4 and the circuit pattern 3 are composed of copper, for example.

A case 6 is bonded to the outer edge portion of the insulating layer 5. The case 6 is provided with an external connection terminal 7, and the semiconductor chip 1 and the circuit pattern 3 are connected to the external connection terminal 7 via wires 8.

A sealing material 9 composed of a thermosetting resin is injected into the case 6 in order to protect the semiconductor chip 1, the wires 8, and the like, accommodated in the case. Further, a lid 10 composed of a thermosetting resin is fitted into an opening of the case 6.

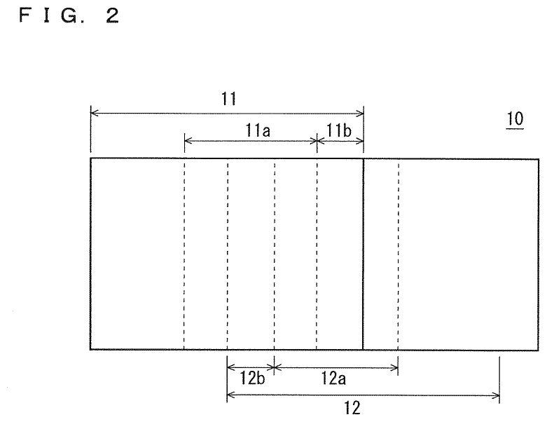

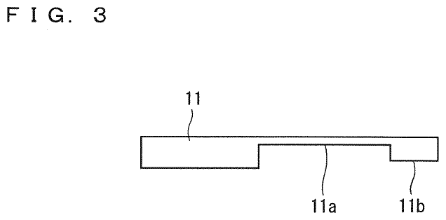

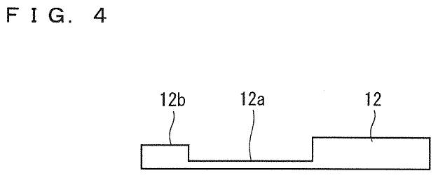

The lid 10 includes a first lid member 11 and a second lid member 12 that partially overlap each other. FIG. 2 illustrates a top view of the lid 10, and FIGS. 3 and 4 illustrate side views of the first lid member 11 and the second lid member 12, respectively.

As illustrated in FIGS. 1 and 2, the first lid member 11 and the second lid member 12 partially overlap each other. As illustrated in FIG. 3, the first lid member 11 has a first notch portion 11a and a first convex portion 11b in a portion overlapping with the second lid member 12. As illustrated in FIG. 4, the second lid member 12 has a second notch portion 12a and a second convex portion 12b in a portion overlapping with the first lid member 11. The lid 10 is constructed of the first lid member 11 and the second lid member 12 that are complementarily combined with each other in a manner of the first lid member 11 and the second lid member 12 combined each other with the second convex portion 12b being inserted into the first notch portion 11a and the first convex portion 11b being inserted into the second notch portion 12a.

In Embodiment 1, the height of the first convex portion 11b and the height of the second convex portion 12b are set to be the same. Therefore, when the first lid member 11 and the second lid member 12 are combined, the first notch portion 11a and the second convex portion 12b come into contact with each other, and the second notch portion 12a and the first convex portion 11b come into contact with each other. Steadfast bonding of the first lid member 11 and the second lid member 12 is thus ensured.

According to the semiconductor device according to Embodiment 1, the lid 10 is composed of the first lid member 11 and the second lid member 12; therefore, when the lid 10 expands due to heat generated during operation, the stress to be received from the inner wall of the case 6 is relaxed. Therefore, warping of the lid 10 can be suppressed and damage to the lid 10 is prevented, contributing to improvement in the reliability of the semiconductor device.

Further, in Embodiment 1, as illustrated in FIGS. 3 and 4, the first lid member 11 and the second lid member 12 are members of the same shape. The first lid member 11 and the second lid member 12, being members of the same shape, suppress a substantial increase in the number of parts.

The configuration in the case 6 illustrated in FIG. 1 is merely an example, and any configuration may be adopted. No restrictions are imposed on the type or material of the semiconductor chip 1. For example, in the case of a semiconductor device for power control, the semiconductor chip 1 can be a Metal Oxide Semiconductor Field Effect Transistor (MOSFET), an Insulated Gate Bipolar Transistor (IGBT), or a Reverse Conductive IGBT (RC-IGBT), a Schottky Barrier Diode (SBD), a PN junction diode, or the like, are used. The semiconductor that is the material of the semiconductor chip 1 may be silicon, or may be a wide bandgap semiconductor such as SiC or GaN. The semiconductor device including the semiconductor chip 1 made of a wide bandgap semiconductor can operate at high temperatures; therefore, the above effects can be highly expected.

### Embodiment 2

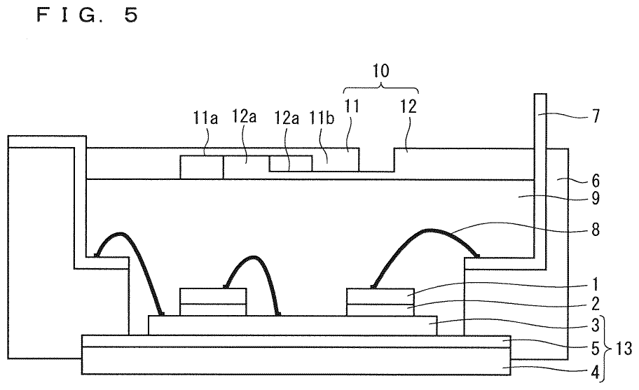

FIG. 5 is cross-sectional view illustrating a configuration of a semiconductor device according to Embodiment 2. The configuration of the semiconductor device according to Embodiment 2 differs from that of the configuration of Embodiment 1 in that the sealing material 9, the first lid member 11, and the second lid member 12 are integrated.

The sealing material 9, the first lid member 11, and the second lid member 12 are 15 all composed of a thermosetting resin, and in the structure illustrated in FIG. 5 is achieved by mounting the lid 10 (the first lid member 11 and the second lid member 12) on the sealing material 9 and curing the sealing material 9 and the lid 10 together. Accordingly, the semiconductor device according to Embodiment 2 can contribute to improvement in manufacturing efficiency.

### Embodiment 3

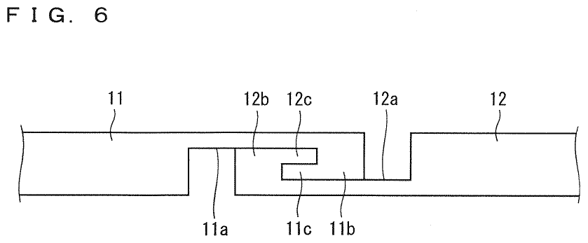

FIG. 6 is a side view of a configuration of a lid 10 in a semiconductor device according to Embodiment 3. As illustrated in FIG. 6, the first lid member 11 of the lid 10 has a first fold-back portion 11c that protrudes from the upper portion of the first convex portion 11b toward the first notch portion 11a side. Similarly, the second lid member 12 of the lid 10 has a second fold-back portion 12c that protrudes from the upper portion of the second convex portion 12b toward the second notch portion 12a side. The lid 10 is constructed by combining the first lid member 11 and the second lid member 12 in such a manner that the first fold-back portion 11c and the second fold-back portion 12c engage with each other.

According to the semiconductor device of Embodiment 3, more steadfast fixation of the first lid member 11 and the second lid member 12 to each other compared to Embodiment 1, obtaining an effect of the first lid member 11 and the second lid member 12 being difficult to remove.

### Embodiment 4

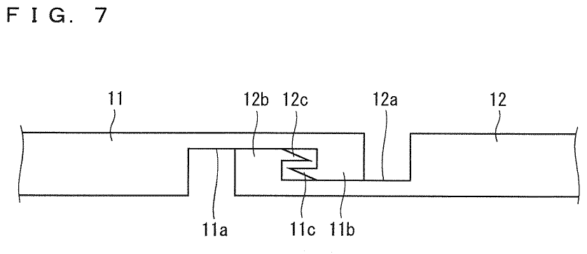

FIG. 7 is a side view of a configuration of a lid 10 in a semiconductor device according to Embodiment 4. The configuration of the lid 10 of the semiconductor device according to Embodiment 4 is the configuration in which a tip of at least one of the first fold-back portion 11c and the second fold-back portion 12c in the configuration of Embodiment 3 (FIG. 6) has an acute angle shape. In FIG. 7, the tips of both the first fold-back portion 11c and the second fold-back portion 12c have an acute angle shape. According to the semiconductor device of Embodiment 4, the first fold-back portion 11c and the second fold-back portion 12c can be engaged more easily than in Embodiment 3.

### Embodiment 5

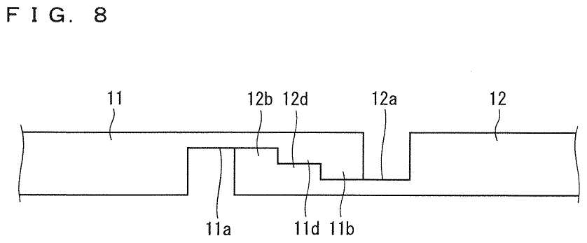

FIG. 8 is a side view of a configuration of a lid 10 in a semiconductor device according to Embodiment 5. As illustrated in FIG. 8, the first lid member 11 of the lid 10 has a first step portion 11d on the first notch portion 11a side of the first convex portion 11b. Similarly, the second lid member 12 of the lid 10 has a second step portion 12d on the second notch portion 12a side of the second convex portion 12b. The first step portion 11d is lower than the first convex portion 11b, and the second step portion 12d is lower than the second convex portion 12b. The height of the first step portion 11d and the second step portion 12d is set such that, the first step portion 11d and the second step portion 12d come into contact with each other when the lid 10 is constructed by combining the first lid member 11 and the second lid member 12.

It is preferable that the difference in height between the first notch portion 11a and the first step portion 11d is equal to the difference in height between the second step portion 12d and the second convex portion 12b and the difference in height between the second notch portion 12a and the second step portion 12d is equal to the difference in height between the first step portion 11d and the first convex portion 11b. When this condition is satisfied, when the first lid member 11 and the second lid member 12 are combined, the first step portion 11d and the second step portion 12d come into contact with each other, the first notch portion 11a and the second convex portion 12b come into contact with each other, and the second notch portion 12a and the first convex portion 11b come into contact with each other. In Embodiment 5, the height of the first convex portion 11b is equal to the height of the second convex portion 12b, the height of the first step portion 11d is set to half the height of the first convex portion 11b, and the height of the second step portion 12d is set to half the height of the second convex portion 12b; therefore, the above condition is satisfied.

Further, if the width of the first step portion 11d and the width of the second step portion 12d are made equal, the side surface of the first convex portion 11b and the side surface of the second step portion 12d can be brought into contact with each other, and the side surface of the second convex portion 12b and the side surface of the first step portion 11d can be brought into contact.

According to the semiconductor device of Embodiment 5, the area of contact between the first lid member 11 and the second lid member 12 when the first lid member 11 and the second lid member 12 are combined is increased, realizing more steadfast bonding.

It should be noted that Embodiments can be arbitrarily combined and can be appropriately modified or omitted.

### Appendix

Hereinafter, the aspects of the present disclosure will be collectively described as Appendices.

### Appendix 1

A semiconductor device comprising:
a case that accommodates a semiconductor chip therein;
a sealing material injected into the case; and
a lid fitted into an opening of the case, wherein
the lid includes a first lid member and a second lid member that partially overlap each other,
the first lid member has a first notch portion and a first convex portion in a portion overlapping with the second lid member,
the second lid member has a second notch portion and a second convex portion in a portion overlapping with the first lid member, and
the first lid member and the second lid member are combined each other with the second convex portion being inserted into the first notch portion and the first convex portion being inserted into the second notch portion.

### Appendix 2

2. The semiconductor device according to Appendix 1, wherein
the sealing material, the first lid member, and the second lid member are integrated.

### Appendix 3

The semiconductor device according to Appendix 1 or 2, wherein
the first lid member has a first fold-back portion that protrudes from the first convex portion toward the first notch portion side,
the second lid member has a second fold-back portion that protrudes from the second convex portion toward the second notch portion side, and
the first fold-back portion and the second fold-back portion engage with each other.

### Appendix 4

The semiconductor device according to Appendix 3, wherein
a tip of at least one of the first fold-back portion and the second fold-back portion has an acute angle shape.

### Appendix 5

The semiconductor device according to Appendix 1 or 2, wherein
the first lid member has a first step portion on a side of the first notch portion of the first convex portion,
the second lid member has a second step portion on a side of the second notch portion of the second convex portion, and
the first step portion and the second step portion are come into contact with each other.

### Appendix 6

The semiconductor device according to any one of Appendices 1 to 5, wherein
the first lid member and the second lid member are members of a same shape.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a case that accommodates a semiconductor chip therein;
a sealing material injected into the case; and
a lid fitted into an opening of the case, wherein
the lid includes a first lid member and a second lid member that partially overlap each other,
the first lid member has a first notch portion and a first convex portion in a portion overlapping with the second lid member,
the second lid member has a second notch portion and a second convex portion in a portion overlapping with the first lid member, and
the first lid member and the second lid member are combined each other with the second convex portion being inserted into the first notch portion and the first convex portion being inserted into the second notch portion.

2. The semiconductor device according to claim 1, wherein
the sealing material, the first lid member, and the second lid member are integrated.

3. The semiconductor device according to claim 1, wherein
the first lid member has a first fold-back portion that protrudes from the first convex portion toward the first notch portion side,
the second lid member has a second fold-back portion that protrudes from the second convex portion toward the second notch portion side, and
the first fold-back portion and the second fold-back portion engage with each other.

4. The semiconductor device according to claim 2, wherein
the first lid member has a first fold-back portion that protrudes from the first convex portion toward the first notch portion side,
the second lid member has a second fold-back portion that protrudes from the second convex portion toward the second notch portion side, and
the first fold-back portion and the second fold-back portion engage with each other.

5. The semiconductor device according to claim 3, wherein
a tip of at least one of the first fold-back portion and the second fold-back portion has an acute angle shape.

6. The semiconductor device according to claim 4, wherein
a tip of at least one of the first fold-back portion and the second fold-back portion has an acute angle shape.

7. The semiconductor device according to claim 1, wherein
the first lid member has a first step portion on a side of the first notch portion of the first convex portion,
the second lid member has a second step portion on a side of the second notch portion of the second convex portion, and
the first step portion and the second step portion are come into contact with each other.

8. The semiconductor device according to claim 2, wherein
the first lid member has a first step portion on a side of the first notch portion of the first convex portion,
the second lid member has a second step portion on a side of the second notch portion of the second convex portion, and
the first step portion and the second step portion are come into contact with each other.

9. The semiconductor device according to claim 1, wherein
the first lid member and the second lid member are members of a same shape.

10. The semiconductor device according to claim 2, wherein
the first lid member and the second lid member are members of a same shape.

11. The semiconductor device according to claim 3, wherein
the first lid member and the second lid member are members of a same shape.

12. The semiconductor device according to claim 4, wherein
the first lid member and the second lid member are members of a same shape.

13. The semiconductor device according to claim 5, wherein
the first lid member and the second lid member are members of a same shape.

14. The semiconductor device according to claim 6, wherein
the first lid member and the second lid member are members of a same shape.

15. The semiconductor device according to claim 7, wherein
the first lid member and the second lid member are members of a same shape.

16. The semiconductor device according to claim 8, wherein
the first lid member and the second lid member are members of a same shape.
